(19) United States
(12) Patent Application Publication
(10) Pub. No.: US 2008/0157251 A1
(43) Pub. Date: Jul. 3, 2008

(54) PACKAGE FOR SEMICONDUCTOR DEVICE AND PACKAGING METHOD THEREOF

(75) Inventor: Hwan-Chul Lee, Incheon (KR)

Correspondence Address: MARGER JOHNSON & MCCOLLOM, P.C., 210 SW MORRISON STREET, SUITE 400, PORTLAND, OR, 97204, US

(73) Assignee: OPTOPAC CO., LTD., Cheongwon-Gun (KR)

(21) Appl. No.: 11/948,716

(22) Filed: Nov. 30, 2007

(30) Foreign Application Priority Data
Dec. 29, 2006 (KR) 10-2006-0137904

(51) Int. Cl. H01L 23/48; H01L 21/02; H01L 31/00

(52) U.S. Cl. 257/434; 257/693; 438/108; 257/E31.117; 257/E23.142; 257/E21.536

(57) ABSTRACT

Provided are an image sensor package used as a semiconductor device package and a method of packaging the image sensor package. The package and method prevent defects in sealing rings and connections for electrical connection during manufacturing process, by designating the melting point of solder balls used for the image sensor package different from the melting point of solder used in other bonding applications.

The semiconductor device package includes a semiconductor device, a substrate assembly, a solder sealing ring, and a plurality of solder balls. The substrate assembly is disposed facing the semiconductor device. The solder sealing ring tightly seals the semiconductor device and the substrate assembly. The solder balls are formed in an outer periphery of the solder sealing ring of the substrate assembly. The solder sealing ring has a higher melting point than the solder balls.

### CROSS-REFERENCE TO RELATED APPLICATION

This application claims priority to Korean Patent Application No. 10-2006-0137904 filed on Dec. 29, 2006 and all the benefits accruing therefrom under 35 U.S.C. §119, the contents of which are incorporated by reference in their entirety.

The present disclosure relates to a semiconductor device package, and more particularly, to an image sensor package that prevents defects in sealing rings and connections for electrical contact during manufacturing process, by designating the melting point of solder balls used for the image sensor package different from the melting point of solder used in other bonding applications, and to a method of packaging the image sensor package.

### BACKGROUND

Image sensors are semiconductor devices capable of capturing images of people and other objects. The image sensors are presently used not only in typical digital cameras and camcorders, but are also mounted in mobile phones, which leads to a sudden growth in the image sensor market since around 1999.

FIG. 1 is a schematic view of a conventional image sensor. As illustrated in FIG. 1, an image sensor (i.e., an image sensor chip 2) includes an image sensing region (generally referred to as a pixel region) 4 in a central region of the device; and terminals (generally referred to as bonding pads) 6 arranged in a peripheral region of the image sensor. The terminal 6 transmits electrical signals of an image captured from pixels, transmits/receives other signals, and supplies electricity. The image sensing region 4 has a plurality of photo diodes formed at the bottom to convert light into electrical signals, color filters of the three primary colors red, green, and blue formed above the photodiodes to separate colors, and microlenses stacked on top of the color filters to focus light on the photodiodes and improve sensitivity. As a schematic view of such an image sensor 2, FIG. 1 illustrates only the image sensing region 4 and the electrodes 6 for the sake of convenience.

In a case of a typical semiconductor device, a package commonly referred to as a plastic package is widely used, which has a structure that is completely sealed with a sealant such as an epoxy resin. In a case of an image sensor, however, because light must reach at least the image sensing region on a surface of the image sensor in order to sense an image, the above-described typical plastic package can't be used.

Ceramic packages having glass covers have been widely used as packages for image sensors. FIG. 2 is a sectional view of a ceramic leadless chip carrier (CLCC) which is widely used as an image sensor package. The related art image sensor package 100 illustrated in FIG. 2 has a light detecting image sensor chip 110 mounted on a ceramic substrate 120 using epoxy, etc. with the surface of the chip facing upward. In order to connect the image sensor chip 110 to the ceramic substrate 120, wires 140 connected to the image sensor chip 110 are connected to contact terminals 150 formed on the bottom of the ceramic substrate 120, and the image sensor package 100 is connected to a circuit board through the contact terminals 150.

While this ceramic package is durable, it is expensive and difficult to miniaturize. Because of these characteristics, this type of ceramic package is employed even nowadays in products such as digital cameras and camcorders that require a high degree of reliability without being restricted by size and cost. On the contrary, the ceramic packages are hardly employed in products such as low-mid level mobile camera phones where pricing competition is fierce and miniaturization is important.

To therefore overcome the above limitation, and fueled by a sudden growth of the mobile camera phone and similar market segments requiring miniaturized components, interest in developing low-cost, miniaturized packages for image sensors has increased.

As an alternative to the ceramic package, chip scale package (CSP) is employed to the image sensor chip. Unlike a chip on board (COB) configuration in which a bare image sensor chip is mounted on a camera module, an image sensor chip is packaged on a wafer level in order to prevent the infiltration of dust or moisture into the image sensing region.

Based on research conducted on image sensor packages, the present disclosure provides a CSP configuration package for an image sensor, which will be described briefly with reference to FIGS. 3A and 3B.

FIGS. 3A and 3B are schematic views of an electronic package for a semiconductor device disclosed in Korean Patent Registration No. 10-0498708 registered on Jun. 22, 2005, which is hereby incorporated by reference.

FIG. 3A is a schematic plan view of a semiconductor device package disclosed in the above-described patented disclosure, and FIG. 3B is a schematic sectional view of the semiconductor device package in FIG. 3A, taken along line A-A′.

As illustrated in FIGS. 3A and 3B, the semiconductor device package includes an image sensor 10 having a sealing region requiring sealing; a substrate assembly 20 disposed facing the image sensor 10, and having metal interconnections 21 formed thereon and a passivation layer 23 formed for protecting the metal interconnections 21; a plurality of flip chip solder joints 13 formed between the image sensor 10 and the substrate assembly 20 to electrically connect the image sensor 10 to the substrate assembly 20; and a plurality of solder balls 25 bonded to the substrate assembly 20 for mounting the package to an external circuit board 30 (not shown).

In order to package a sealing region 10a of the image sensor 10, a solder sealing ring 11 is formed around the sealing region 10a of the image sensor 10 between the image sensor 10 and substrate assembly 20, in order to prevent the infiltration of impurities into a space (sealing region 10a) between the substrate assembly 20 and the image sensor 10.

When comparing the above-configured semiconductor device package to the CLCC in FIG. 2 which requires both a multi-layer ceramic substrate for its electrical connection and a glass cover for transmitting light, the semiconductor device package in FIGS. 3A and 3B has a significantly simpler structure by incorporating both of the above functions into a glass substrate.

A method of manufacturing the semiconductor device package in FIGS. 3A and 3B generally includes: preparing an image sensor and a substrate assembly; and pre-bonding the solder sealing ring and the flip chip solder joint formed between the image sensor and the substrate assembly through a reflow soldering process. In order to mount this package to an external circuit board, the solder balls on the semiconductor device package are disposed to face the external circuit board, and then bonded to the external circuit board through reflow soldering.

In accordance with the related art, the solder sealing ring, the flip chip solder joint, and the solder balls are formed of the same type of solder, so that their respective melting points are the same. Therefore, the solder sealing ring and the flip chip solder joint can be melted during the process of bonding the solder ball, because the solder sealing ring and the flip chip solder joint are pre-bonded to attach the substrate assembly to the image sensor, which results in deterioration of the package for the image sensor induced by the melted solder sealing ring, and electrical connection defects caused by the melted flip chip solder joint.

Furthermore, severe melting of the solder sealing ring can lead to separation of the substrate assembly and the semiconductor device.

### SUMMARY

The present disclosure provides a semiconductor device package and a packaging method thereof capable of preventing defects of solder sealing ring and flip chip solder joint during mounting of the package on an external circuit board, by designating the melting point of solder balls used on the semiconductor device package different from the melting point of other bonding solder.

In accordance with an exemplary embodiment, a semiconductor device package apparatus includes: a semiconductor device; a substrate assembly disposed facing the semiconductor device; a solder sealing ring tightly sealing the semiconductor device and the substrate assembly; and a plurality of solder balls disposed in an outer periphery of the solder sealing ring of the substrate assembly, wherein the solder sealing ring has a higher melting point than the solder ball.

The semiconductor device package may further include a plurality of flip chip solder joints between the semiconductor device and the substrate assembly to electrically connect the semiconductor device with the substrate assembly, wherein the flip chip solder joint may have the same melting point as the solder sealing ring.

The melting point of the solder sealing ring and the flip chip solder joints may be higher than the melting point of the solder ball by approximately 30° C. to 60° C. The melting point of the solder sealing ring and the flip chip solder joint may be in a range of approximately 210° C. to 240° C., and the melting point of the solder balls may be in a range of approximately 170° C. to 200° C.

The semiconductor device may be an image sensor, and the substrate assembly may have light transmissivity.

In accordance with another exemplary embodiment, a method of packaging a semiconductor device, includes: forming a solder sealing ring on the semiconductor device; bonding a solder ball on a substrate assembly, the solder ball having a lower melting point than the solder sealing ring; tightly sealing the semiconductor device and the substrate assembly through positioning the substrate assembly to face the semiconductor device and bonding the solder sealing ring; and bonding the solder ball to an external circuit board after positioning the substrate assembly on the external circuit board.

Forming the solder sealing ring may further include forming a plurality of flip chip solder joints having the same melting point as the melting point of the solder sealing ring in an outer periphery of the solder sealing ring. Tightly sealing the semiconductor device and the substrate assembly may further include bonding the flip chip solder joints together to the bonding of the solder sealing ring to electrically connect the semiconductor device with the substrate assembly.

Bonding the solder ball may include heating the solder ball to a reflow temperature higher than the melting point of the solder ball and lower than the melting point of the solder sealing ring.

### BRIEF DESCRIPTION OF THE DRAWINGS

Exemplary embodiments can be understood in more detail from the following description taken in conjunction with the accompanying drawings, in which:

FIG. 1 is a schematic view of a conventional image sensor;

FIG. 2 is a schematic sectional view of a related art ceramic package for an image sensor;

FIG. 3A is a schematic plan view of a semiconductor device package used in the present disclosure;

FIG. 3B is a schematic sectional view taken along line A-A′ of FIG. 3A; and

FIGS. 4A through 4C are sectional views illustrating a process of assembling a semiconductor device and a substrate assembly, and mounting the package on an external circuit board, in accordance with an exemplary embodiment.

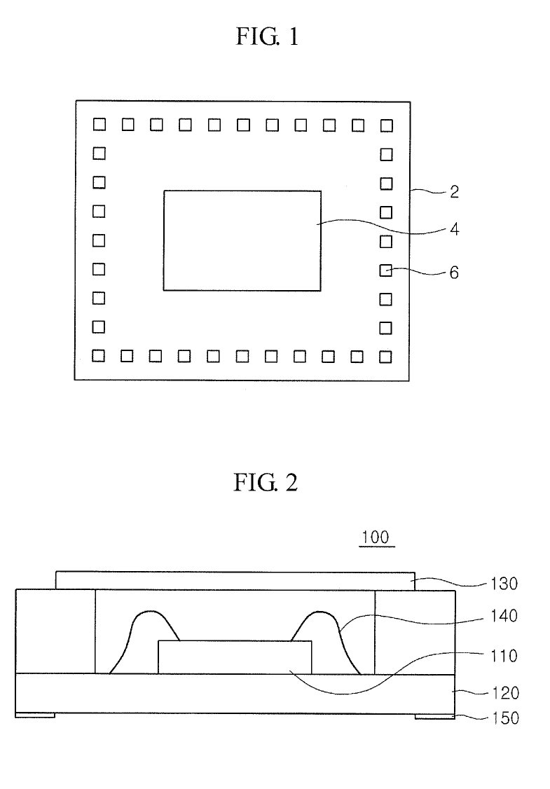

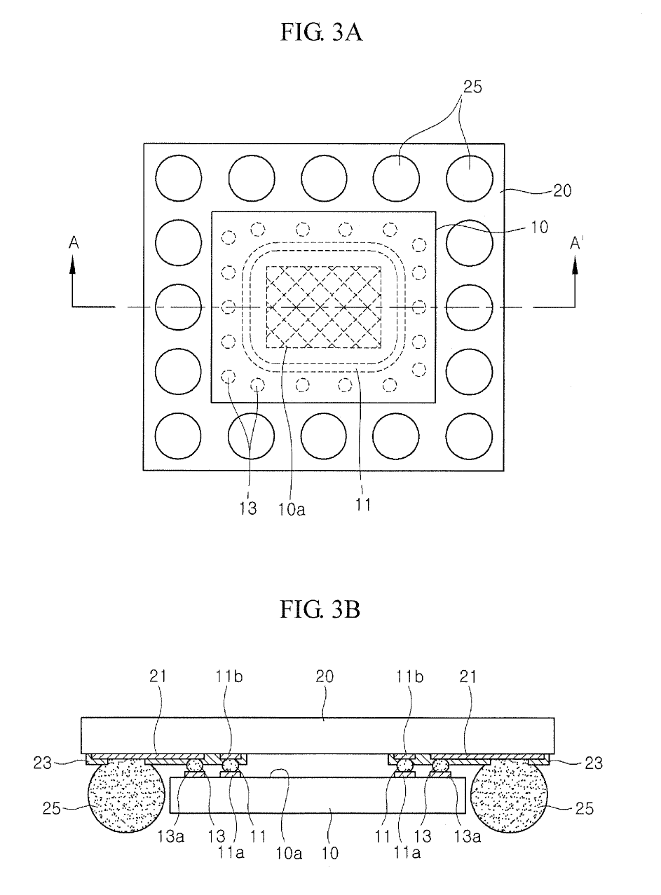

### DETAILED DESCRIPTION OF EMBODIMENTS

A semiconductor device which is a component of various apparatuses and electrical circuits typically has a packaging structure. The semiconductor device and packaging structure will collectively be referred to as a ‘semiconductor device package’ hereinafter.

The semiconductor device package structure in accordance with an exemplary embodiment is configured such that the melting point of the flip chip solder joint is higher than the melting point of the solder ball, wherein the flip chip solder joint electrically connects the semiconductor device and solder sealing ring for packaging the sealing region of the semiconductor device package to the substrate assembly, and wherein the solder ball connects the package to an external circuit board. The configuration of the semiconductor device package in accordance with the exemplary embodiment will be described below together with the melting points of the solder sealing rings, flip chip solder joints, and solder balls.

Hereinafter, exemplary embodiments will be described in detail with reference to the accompanying drawings.

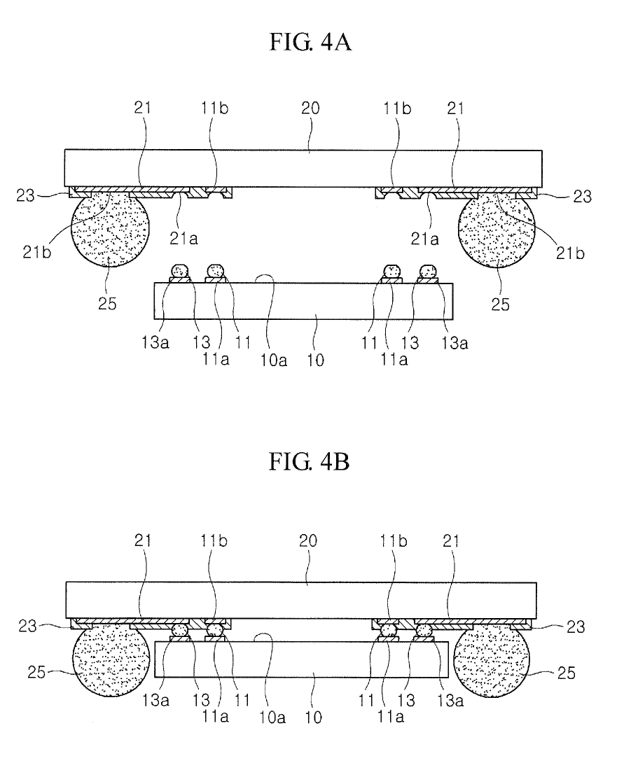

FIG. 3A is a schematic plan view of a semiconductor device package used in the present disclosure, and FIG. 3B is a schematic sectional view taken along line A-A′ of FIG. 3A.

Referring to FIGS. 3A and 3B, a semiconductor device package in accordance with the present disclosure includes a semiconductor device 10, and a substrate assembly 20 disposed facing the semiconductor device 10.

The semiconductor device 10 may be any semiconductor devices having a sealing region 10a, and an image sensor is used in the descriptions in accordance with the present disclosure.

As an image sensor is selected as the semiconductor device 10, the substrate assembly 20 accordingly employs a transparent material, for example, a glass substrate.

A solder sealing ring 11 is formed to surround the sealing region 10a between the semiconductor device 10 and the substrate assembly 20 to package the sealing region 10a.

The solder sealing ring 11 can have any shape enabling packaging the sealing region 10a. For example, the solder sealing ring may have a shape of a closed loop, an open loop with predetermined width and length and an air passage. The solder sealing ring may be formed as a combination of an open loop-shaped solder sealing ring having a predetermined width and one or two auxiliary solder sealing rings having a width near the open portion, may have various other configurations. The present disclosure exemplarily describes a solder sealing ring having a shape of a closed loop.

As exemplified, the solder sealing ring 11 may have various shapes, and use a solder material with a melting point in a range of approximately 210° C. to 240° C. The solder material used in the solder sealing ring 11 in accordance with the present disclosure may have a melting point of approximately 217° C. For example, a Pb-free solder having a composition of 95.7% Sn, 3.8% Ag, and 0.5% Cu is used.

A plurality of solder balls 25 for electrically connecting the package to an external circuit board 30 is bonded to the substrate assembly 20.

The semiconductor device 10 should be electrically connected to the substrate assembly 20. As illustrated in FIGS. 3A and 3B, the semiconductor device package in accordance with the present disclosure further includes a plurality of flip chip solder joints 13 to electrically connect the semiconductor device 10 to the substrate assembly 20.

A solder used in the flip chip solder joint 13 may have the same melting point as the solder used in the solder sealing ring 11. The Pb-free solder used in the solder sealing ring 11 having a melting point of approximately 217° C. and a composition of 95.7% Sn, 3.8% Ag, and 0.5% Cu is also used for the flip chip solder joint 13 in the exemplary embodiment of the present invention.

Also, the solder balls 25 used on the substrate assembly 20 is formed of a material having a lower melting point than the solder sealing ring 11 and the flip chip solder joint 13. The material used in the solder balls 25 may have a lower melting point than the solder used in the solder sealing ring 11 and the flip chip solder joint 13 by approximately 30° C. to 60° C.

During a typical surface mount technology (SMT) process, a reflow process of the solder is performed as the solder passes through a reflow oven at a temperature higher than the melting point of the solder by approximately 30° C. in order to properly bond the solder. Thus, degradation of bonded state of the solder sealing ring 11 and the flip chip solder joint 13 can be avoided by using the solder material of which melting point is higher than that of the solder ball by 30° C. to 60° C. while bonding the solder ball 25.

Accordingly, even if the reflow temperature is raised to be higher than the melting point of solder balls 25 by approximately 30° C. in order to bond the solder balls 25 placed on a substrate assembly 20 in the SMT process, the solder sealing ring 11 and the flip chip solder joint 13 are not affected by the raised temperature because the reflow temperature is similar to or lower than melting points of a solder sealing ring 11 and flip chip solder joint 13 placed between the semiconductor device 10 and the substrate assembly 20.

Therefore, a material having a melting point in a range of approximately 170° C. to 200° C. is used for the solder balls 25, and may have a composition of 37% Pb and 63% Sn and a melting point of approximately 183° C.

A method of packaging the above-configured semiconductor device package will be described below in detail with reference to the drawings.

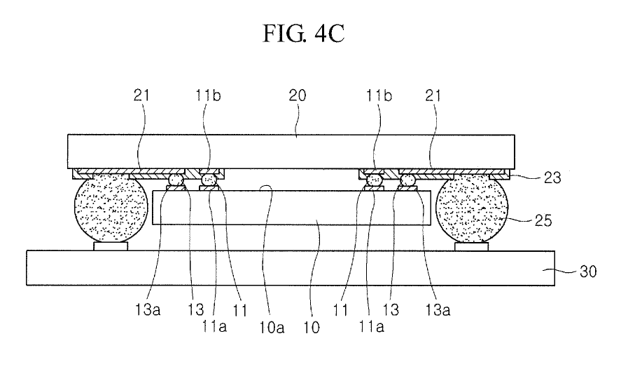

FIGS. 4A through 4C are sectional views illustrating a process of assembling a semiconductor device and a substrate assembly, and mounting the package on an external circuit board in accordance with an exemplary embodiment.

A method of packaging a semiconductor device package in accordance with the exemplary embodiment includes forming a solder sealing ring 11 for enclosing a sealing region 10a on the semiconductor device 10 and for packaging the sealing region 10a.

Manufacturing of the semiconductor device 10 begins with manufacturing a semiconductor wafer including a plurality of semiconductor devices. Typically the semiconductor wafer is manufactured and supplied by a chip maker up to a stage commonly referred to as a fab-out stage. Following the fab-out stage, a post process is required to employ the product in such a package according to the exemplary embodiment of the present invention. For the sake of convenience, only the post process will be addressed below.

The post process is called a flip chip solder bumping. Generally, in order to form a solder bonding connection, pads to which the solder sealing ring 11 can be fusion-bonded are formed. Also, pads to which the flip chip solder joint 13 can be fusion-bonded may be formed simultaneously with the pads to which the solder sealing ring 11 is fusion-bonded depending on configurations of the semiconductor device packages.

The above pads are formed on the semiconductor device 10 and the substrate assembly to be corresponding to the solder sealing ring 11 and flip chip solder joint 13. An under bump metallurgy (UBM) layer is formed on a wafer and patterned to form the pads. In this way, a plurality of solder sealing ring pads 11a and flip chip joint pads 13a are provided to correspond to the solder sealing ring 11 and the flip chip solder joint 13, respectively.

After the solder sealing ring pads 11a and flip chip solder joint pads 13a are provided on the semiconductor device 10 through the above process, the solder sealing ring 11 and flip chip solder joint 13 are respectively formed on the semiconductor device 10 on the corresponding pads 11a and 13a.

The solder sealing ring 11 and the flip chip solder joint 13 may be formed through typical electroplating or printing methods. Also, as described above, the Pb-free solder having a composition of 95.7% Sn, 3.8% Ag, and 0.5% Cu and a melting point of approximately 217° C. may be used for the solder sealing ring 11 and flip chip solder joint 13.

The light transmitting substrate assembly 20 is then positioned to face the semiconductor device 10.

The substrate assembly 20 is formed by defining at least one unit substrate to be electrically connected to the semiconductor device 10; forming at least one metal layer on the upper surface of the unit substrate and patterning the metal layer to form metal interconnections 21; and forming a passivation layer 23 to protect the metal interconnections 21.

Forming the metal interconnections 21 or forming the passivation layer 23 may employ semiconductor techniques well known to those skilled in the art.

The metal interconnections 21 and passivation layer 23 include two types of contact terminals 21a and 21b for electrical connections, and a solder sealing ring pad 11b corresponding to the solder sealing pad 11a provided on the semiconductor device 10.

One 21a of the two types of contact terminals 21a and 21b is for forming the flip chip solder joint 13 bonded to the semiconductor device 10, and the other 21b is for electrical connection of the package to the external circuit board 30. A plurality of solder balls 25 is fusion-bonded to this contact terminal 21b.

A material having a lower melting point than the solder sealing ring 11 and the flip chip solder joint 13 is used for the solder ball 25. More particularly, a material having a lower melting point than the solder sealing ring 11 and the flip chip solder joint 13 by approximately 30° C. to 60° C. may be used.

In the exemplary embodiment, therefore, the solder ball having a composition of 37% Pb and 63% and a melting point of approximately 183° C. is used.

When the substrate assembly 20 is prepared as above, a plurality of semiconductor devices 10 formed on a semiconductor wafer are separated and the substrate assembly 20 is positioned over a semiconductor device 10 so that the solder sealing ring 11 and flip chip solder joint 13 of the semiconductor device 10 are brought into contact with the corresponding solder sealing ring pad 11b and the contact terminal 21a of the metal interconnection 21, as illustrated in FIG. 4A.

Then, as illustrated in FIG. 4B, the substrate assembly 20 is heated through reflow soldering to a temperature higher than the melting point of the solder sealing ring 11 and the flip chip solder joint 13 by approximately 20° C. to 30° C., and thereby the solder sealing ring 11 and the plurality of flip chip solder joints 13 are fusion-bonded.

Although the solder balls 25 fusion-bonded to the substrate assembly 20 can be melted during the fusion-bonding of the solder sealing ring 11 and the flip chip solder joints 13, the solder balls 25 are capable of retaining their shape due to surface tension.

When the package is prepared as described above, the package is then positioned at an appropriate position of the external circuit board 30 so that the solder balls 25 are correctly positioned, and the solder balls 25 are heated through reflow soldering to mount the package on the external circuit board 30 as illustrated in FIG. 4C. The solder balls 25 are fusion-bonded by heating to a temperature which is higher than the melting point of the solder ball 25 and lower than the melting point of the solder sealing ring 11 and the flip chip solder joints 13.

That is, because the reflow temperature during the bonding of the solder balls 25 is lower than the melting point of the solder sealing ring 11 and the flip chip solder joint 13, the bonding state of the solder sealing ring 11 and the flip chip solder joint 13 are not affected by the temperature and the solder balls 25 can be uniformly fusion-bonded.

According to the exemplary embodiment of the present invention, the semiconductor device is packaged by fusion-bonding the plurality of solder balls 25 during a stage of forming the substrate assembly 20, and then by packaging the semiconductor device 10 and the substrate assembly 20 using a solder sealing ring 13. Alternately, the solder balls 25 may be bonded to a separate substrate assembly after the semiconductor device 10 and the substrate assembly 20 are packaged using the solder sealing ring 13 before the substrate assembly 20 is mounted on an external circuit board 30.

In any cases, the solder ball 25 is heated to a temperature higher than the melting point of the solder balls 25 and lower than the melting point of the solder sealing ring 11 and the flip chip solder joint 13 so that the bonded states of the solder sealing ring 11 and the flip chip solder joint 13 are not affected.

As described, in the semiconductor device package and packaging method thereof in accordance with the exemplary embodiments, the melting point of the solder sealing ring and flip chip solder joint that are fusion-bonded between the semiconductor device and substrate assembly are designed to be different from the melting point of the solder balls that are fusion-bonded between the substrate assembly and the external circuit board. Therefore, a reliability of the bonded states of the solder sealing ring and the flip chip solder joint can be ensured during fusion-bonding of the solder balls, whereby defects in the sealing ring and solder joint portions generated during manufacturing process can be prevented.

Although the semiconductor device package and the packaging method thereof have been described with reference to the exemplary embodiments, the present invention is not limited thereto. Therefore, it will be readily understood by those skilled in the art that various modifications and changes can be made thereto without departing from the spirit and scope of the present disclosure defined by the appended claims.

What is claimed is:

1. A semiconductor device package, comprising:
a semiconductor device;
a substrate assembly disposed facing the semiconductor device;
a solder sealing ring tightly sealing the semiconductor device and the substrate assembly; and
a plurality of solder balls disposed in an outer periphery of the solder sealing ring of the substrate assembly,
wherein the solder sealing ring has a higher melting point than the solder ball.

2. The semiconductor device package of claim 1, wherein the semiconductor device is an image sensor, and the substrate assembly has light transmissivity.

3. The semiconductor device package of claim 1, further comprising a plurality of flip chip solder joints between the semiconductor device and the substrate assembly to electrically connect the semiconductor device to the substrate assembly, wherein the flip chip solder joint has the same melting point as the solder sealing ring.

4. The semiconductor device package of claim 3, wherein the melting point of the solder sealing ring and the flip chip solder joint is higher than the melting point of the solder ball by approximately 30° C. to 60° C.

5. The semiconductor device package of claim 4, wherein the melting point of the solder sealing ring and the flip chip solder joint is in a range of approximately 210° C. to 240° C., and the melting point of the solder balls is in a range of approximately 170° C. to 200° C.

6. The semiconductor device package of claim 3, wherein the semiconductor device is an image sensor, and the substrate assembly has light transmissivity.

7. A method of packaging a semiconductor device, comprising:
forming a solder sealing ring on the semiconductor device;
bonding a solder ball on a substrate assembly, the solder ball having a lower melting point than the solder sealing ring;
tightly sealing the semiconductor device and the substrate assembly through positioning the substrate assembly to face the semiconductor device and bonding the solder sealing ring; and
bonding the solder ball to an external circuit board after positioning the substrate assembly on the external circuit board.

8. The method of claim 7, wherein forming the solder sealing ring further comprises forming a plurality of flip chip solder joints having the same melting point as the melting point of the solder sealing ring in an outer periphery of the solder sealing ring, and
tightly sealing the semiconductor device and the substrate assembly further comprises bonding the flip chip solder joints together to electrically connect the semiconductor device with the substrate assembly.

9. The method of claim 7, wherein bonding the solder ball comprises heating the solder ball to a reflow temperature higher than the melting point of the solder ball and lower than the melting point of the solder sealing ring.
